(19) United States
(12) Patent Application Publication
(10) Pub. No.: US 2025/0048812 A1
(43) Pub. Date: Feb. 6, 2025

(54) MANUFACTURING METHOD OF LIGHT-EMITTING DEVICE, AND LIGHT-EMITTING DEVICE

(71) Applicant: NICHIA CORPORATION, Anan-shi (JP)

(72) Inventor: Kota OKURA, Anan-shi (JP)

(73) Assignee: NICHIA CORPORATION, Anan-shi (JP)

(21) Appl. No.: 18/791,922

(22) Filed: Aug. 1, 2024

(30) Foreign Application Priority Data
Aug. 3, 2023 (JP) 2023-127299

(51) Int. Cl. H01L 33/60; H01L 33/56

(52) U.S. Cl. CPC H01L 33/60; H01L 33/56; H01L 2933/005; H01L 2933/0058

(57) ABSTRACT

A method of manufacturing a light-emitting device according to an aspect of the present disclosure includes: providing a light-emitting device intermediate including a light-emitting element and a covering member intermediate that contains a light reflective material and an alkali metal silicate and covers the light-emitting element; and immersing the covering member intermediate in an aqueous solution containing an alkaline earth metal halide salt to form a covering member containing an alkaline earth metal silicate.

### CROSS-REFERENCE TO RELATED APPLICATION

This application claims priority to Japanese Patent Application No. 2023-127299, filed on Aug. 3, 2023, the disclosure of which is hereby incorporated by reference in its entirety.

### TECHNICAL FIELD

The present disclosure relates to a method of manufacturing a light-emitting device, and a light-emitting device.

### BACKGROUND

There is known a light-emitting device including a light-emitting element and a covering member formed of an inorganic member that covers a part of the light-emitting element (See for example, Japanese Patent Publication No. 2022-58212).

### SUMMARY

Such a covering member formed of the inorganic member still has room for improvement to improve the performance of the light-emitting device.

An object of an embodiment of the present disclosure is to provide a method of manufacturing a light-emitting device with high reliability.

A method of manufacturing a light-emitting device according to an embodiment of the present disclosure includes: providing a light-emitting device intermediate including a light-emitting element and a covering member intermediate that contains a light reflective material and an alkali metal silicate and covers the light-emitting element; and immersing the covering member intermediate in an aqueous solution containing an alkaline earth metal halide salt to form a covering member containing an alkaline earth metal silicate.

According to an embodiment of the present disclosure, the light-emitting device with high reliability can be manufactured.

### BRIEF DESCRIPTION OF DRAWINGS

FIG. 1 is a schematic cross-sectional view of a light-emitting device according to an embodiment of the present disclosure.

FIG. 2A is a schematic cross-sectional view for describing a method of manufacturing the light-emitting device according to an embodiment (first).

FIG. 2B is a schematic cross-sectional view for describing the method of manufacturing the light-emitting device according to an embodiment (second).

FIG. 2C is a schematic cross-sectional view for describing the method of manufacturing the light-emitting device according to an embodiment (third).

FIG. 2D is a schematic cross-sectional view for describing the method of manufacturing the light-emitting device according to an embodiment (fourth).

FIG. 2E is a schematic cross-sectional view for describing the method of manufacturing the light-emitting device according to an embodiment (fifth).

FIG. 3 is a graph showing resistivities of a covering member intermediate and a covering member according to an example.

### DETAILED DESCRIPTION

Hereinafter, embodiments for carrying out the disclosure will be described with reference to the drawings. Note that, in the following description, terms indicating a specific direction or position (e.g., “upper”, “upward”, “lower”, “downward” and other terms including those terms) are used as necessary. The use of those terms, however, is to facilitate understanding of the disclosure with reference to the drawings, and the technical scope of the present disclosure is not limited by the meanings of those terms. Parts having the same reference signs appearing in a plurality of drawings indicate identical or equivalent parts or members.

Further, the following embodiments exemplify light-emitting devices and the like for embodying the technical concept of the present disclosure, and the present disclosure is not limited to the description below. The dimensions, materials, shapes, relative arrangements, and the like of constituent components described below are not intended to limit the scope of the present disclosure to those alone, but are intended to provide an example, unless otherwise specified. The contents described in one embodiment can be applied to the other embodiment and a variation. The sizes, positional relationship, and the like of the members illustrated in the drawings can be exaggerated in order to clarify the explanation. Furthermore, in order to avoid excessive complication of the drawings, a schematic view in which some elements are not illustrated may be used, or an end view illustrating only a cutting surface may be used as a cross-sectional view.

### Method of Manufacturing Light-Emitting Device

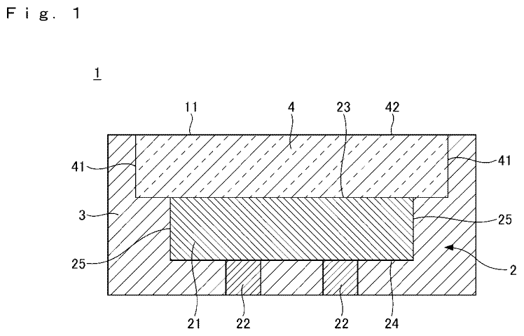

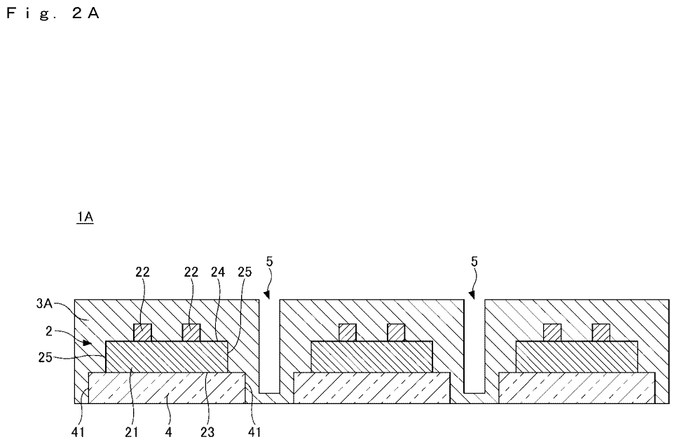

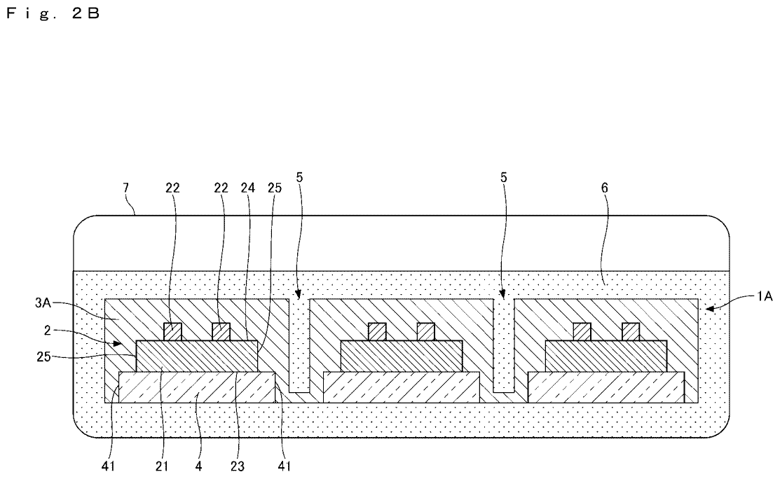

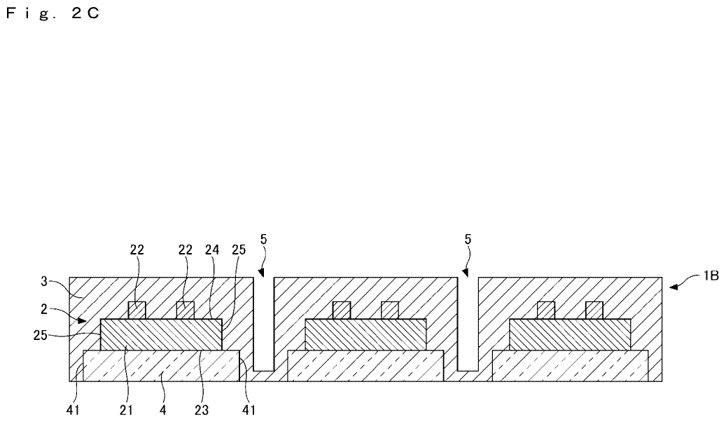

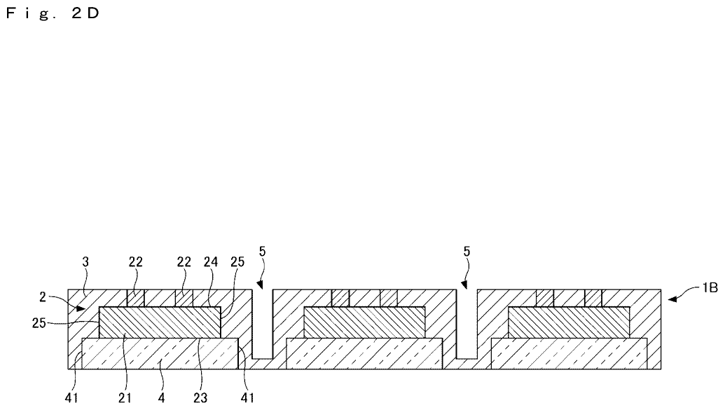

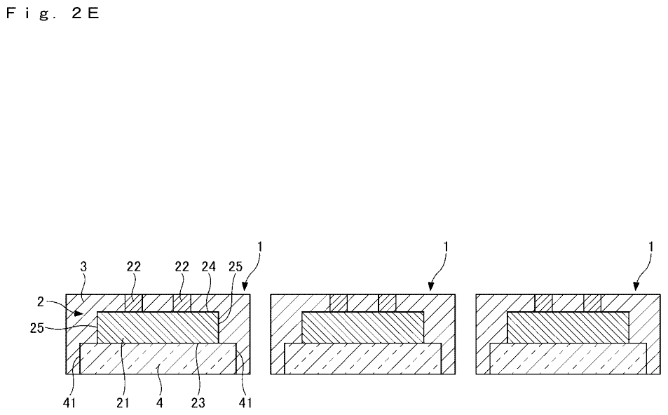

FIG. 1 is a schematic cross-sectional view of a light-emitting device 1 according to an embodiment. FIGS. 2A to 2E are schematic cross-sectional views for describing a method of manufacturing the light-emitting device 1 according to an embodiment. The light-emitting device 1 of the present embodiment includes a light-emitting element 2 and a covering member 3 that contains a light reflective material and alkaline earth metal silicate and covers the light-emitting element 2. An example of the method of manufacturing the light-emitting device 1 according to the present embodiment will be described below with reference to FIGS. 2A to 2E.

The method of manufacturing the light-emitting device 1 of the present embodiment includes a step of providing a light-emitting device intermediate 1A including the light-emitting elements 2 and a covering member intermediate 3A that contains a light reflective material and alkali metal silicate and covers the light-emitting elements 2 as illustrated in FIG. 2A, and a step of forming a covering member 3 containing alkaline earth metal silicate by immersing the covering member intermediate 3A in an alkaline earth metal halide salt aqueous solution 6 as illustrated in FIG. 2B.

According to the method of manufacturing the light-emitting device 1 described above, the light-emitting device 1 with high reliability can be manufactured. Details will be described below.

According to the method of manufacturing the light-emitting device 1 described above, by immersing the covering member intermediate 3A in the alkaline earth metal halide salt aqueous solution, alkali metal of the alkali metal silicate constituting the covering member intermediate 3A can be replaced by the alkaline earth metal in the alkaline earth metal halide salt aqueous solution 6. Because the alkaline earth metal silicate has lower solubility in water than the alkali metal silicate, the alkaline earth metal silicate is less likely to react with, for example, moisture present in the atmosphere. Therefore, generation of metal ions due to a reaction with moisture can be reduced. As a result, the occurrence of a leakage current caused by contact of the metal ions with an electrode of the light-emitting element 2 can be reduced.

### Step of Providing Light-Emitting Device Intermediate 1A

The method of manufacturing the light-emitting device 1 of the present embodiment includes the step of providing the light-emitting device intermediate 1A including the light-emitting elements 2 and the covering member intermediate 3A containing the light reflective material and the alkali metal silicate and covering the light-emitting elements 2 as illustrated in FIG. 2A. The light-emitting device intermediate 1A is a light-emitting device intermediate before the alkali metal of the alkali metal silicate constituting the covering member intermediate 3A is replaced by the alkaline earth metal in the alkaline earth metal halide salt aqueous solution 6. In the example illustrated in FIG. 2A, the light-emitting device intermediate 1A (that is, the light-emitting device intermediate before replacement) includes a plurality of the light-emitting elements 2, the covering member intermediate 3A that covers the plurality of light-emitting elements 2 and links adjacent ones of the light-emitting elements 2 to one another, and a plurality of light-transmissive members 4. The term “covers” includes a state of covering in contact with the light-emitting elements 2 and a state of covering via another member or a gap, such as an air layer, between the covering member intermediate 3A and the light-emitting elements 2. The light-emitting device intermediate 1A is not limited to including the plurality of light-emitting elements 2, and may include one light-emitting element 2. The light-emitting device intermediate 1A is not limited to including the light-transmissive member 4, and need not include the light-transmissive member 4. The number of light-transmissive members 4 is not limited to a plurality, and may be one.

A semiconductor light-emitting element, such as a light emitting diode (LED) chip or a semiconductor laser (LD) chip, can be suitably used for the light-emitting element 2. In the example illustrated in FIG. 1, the light-emitting element 2 includes a semiconductor structure 21 and electrodes 22. The light-emitting element 2 has a light-emitting surface 23, an electrode-forming surface 24 that is a surface located at the opposite side of the light-emitting surface 23 and on which the electrodes 22 are provided, and lateral surfaces 25 connecting the light-emitting surface 23 and the electrode-forming surface 24.

The semiconductor structure 21 includes an n-side semiconductor layer, a p-side semiconductor layer, and a light-emitting layer interposed between the n-side semiconductor layer and the p-side semiconductor layer. The light-emitting layer may have a single quantum well (SQW) structure, or may have a multi quantum well (MQW) structure including a plurality of well layers. The semiconductor structure 21 includes a plurality of semiconductor layers formed of a nitride semiconductor. The nitride semiconductor includes a semiconductor having all compositions in which in a chemical formula of InₓAl_{y}Ga_{1-x-y}N (0≤x, 0≤y, and x+y≤1), and composition ratios x and y are changed within respective ranges. The emission peak wavelength of the light-emitting layer can be selected as appropriate according to the purpose. The light-emitting layer is configured, for example, so as to be able to emit visible light or ultraviolet light.

The light-emitting element 2 may or does not have to include a light-transmissive support substrate on the surface side of the semiconductor structure 21 located at the opposite side to the electrode-forming surface 24. When the light-emitting element 2 includes the support substrate, a surface of the support substrate located at the opposite side to a surface facing the semiconductor structure 21 serves as the light-emitting surface 23 of the light-emitting element 2. When the light-emitting element 2 does not include the support substrate, a surface of the semiconductor structure 21 located at the opposite side to the electrode-forming surface 24 serves as the light-emitting surface 23 of the light-emitting element 2.

The light-emitting element 2 may have one semiconductor structure 21 provided on a primary surface of one support substrate, or may have a plurality of the semiconductor structures 21 provided on the primary surface of one support substrate. In addition, one semiconductor structure 21 may include only one light-emitting layer or may include a plurality of the light-emitting layers. The semiconductor structure 21 including the plurality of light-emitting layers may have a structure including the plurality of light-emitting layers between one n-side semiconductor layer and one p-side semiconductor layer, or may have a structure including the n-side semiconductor layer, the light-emitting layer, and the p-side semiconductor layer in sequence, repeated multiple times.

Examples of the material of the support substrate include a nitride semiconductor, such as sapphire, spinel (MgAl₂O₄), and gallium nitride.

The light-emitting element 2 can have any shape in plan view. The shape of the light-emitting element 2 in plan view is, for example, a quadrangle (such as a square or a rectangle), a triangle, or a hexagon. When the shape of the light-emitting elements 2 is a quadrangle in plan view, the size of the light-emitting element 2 can be, for example, 1 mm×1 mm. The term “plan view” in the present specification means observation from the side of the light-emitting surface 23 of the light-emitting element 2.

In the example illustrated in FIG. 2A, the covering member intermediate 3A covers the electrode-forming surface 24 and the lateral surfaces 25 of the light-emitting element 2 and lateral surfaces 41 of the light-transmissive member 4. In addition, when the covering member intermediate 3A covers the electrode-forming surface 24 of the light-emitting element 2, in the example illustrated in FIG. 2A, the covering member intermediate 3A covers the surfaces of the electrodes 22 located at the opposite side to the surface at the semiconductor structure 21 side. However, the configuration is not limited to this, and the covering member intermediate 3A does not have to cover the surfaces of the electrodes 22 located at the opposite side to the surface at the semiconductor structure 21 side.

The light reflective material included in the covering member intermediate 3A can reflect light emitted from the light-emitting elements 2. The material of the light reflective material is boron nitride or aluminum oxide, for example. Because boron nitride or aluminum oxide is a material having good thermal conductivity, the covering member intermediate 3A having an good heat dissipation property can be obtained. In addition, these materials function as aggregates of the covering member intermediate 3A when heated to form the covering member intermediate 3A. Thus, contraction of the covering member intermediate 3A due to heat can be reduced.

The light reflective material is, for example, plate-like (including scale-like) particles having two primary surfaces. The light reflective material may be primary particles, or secondary particles as an agglomeration of two or more primary particles. In addition, the light reflective material may be a mixture of the primary particles and the secondary particles.

An average aspect ratio of the primary particles of the light reflective material is preferably 10 or more, and more preferably in a range from 10 to 70. In a case in which the light reflective material is boron nitride, the average aspect ratio of the light reflective material is in a range from 16.5 to 19.2, for example. In a case in which the light reflective material is aluminum oxide, the average aspect ratio of the light reflective material is in a range from 10 to 70, for example. The average aspect ratio of the light reflective material can be calculated by the following method, for example.

### Calculation Method of Average Aspect Ratio

The average aspect ratio of the light reflective material is calculated by measuring a length of a major axis and a length of a minor axis of the light reflective material included in the covering member intermediate 3A in a cross section of the light-emitting device intermediate 1A after manufacturing the light-emitting device intermediate 1A. First, a cross section that passes through the center of the light-emitting surface 23 of the light-emitting element 2 and is substantially orthogonal to the light-emitting surface 23 is exposed. Subsequently, the exposed cross section is mirror polished. The mirror-polished cross section is observed with a scanning electron microscope (SEM) at magnifications in a range from 2000 to 3000, the cross section of the light reflective material is extracted from the obtained image, and a measurement region including approximately 1000 cross sections of the light reflective material is selected. The average aspect ratio of the light reflective material can be calculated by measuring the length of the major axis and the length of the minor axis of the light reflective material included in the covering member 3 in the cross section of the light-emitting device 1 after manufacturing the light-emitting device 1.

Subsequently, with image analysis software, each one point of the extracted length of the major axis and length of the minor axis of the cross section of each particle of the light reflective material are measured to calculate a ratio of the length of the major axis to the length of the minor axis (the aspect ratio). Then, the average value of the aspect ratios of 100 particles of the light reflective material is set as the average aspect ratio.

The average particle diameter of the light reflective material is preferably in a range from 0.6 μm to 43 μm. In a case in which the light reflective material is boron nitride, the average particle diameter of the light reflective material is in a range from 6 μm to 43 μm, for example. In a case in which the light reflective material is aluminum oxide, the average particle diameter of the light reflective material is in a range from 0.6 μm to 10 μm, for example.

Here, because deformation or deterioration of the light reflective material due to the manufacturing process is slight, the shape and dimensions of the light reflective material powder are substantially the same as the shape and dimensions of the light reflective material included in the covering member intermediate 3A or the covering member 3. Therefore, the average particle diameter of the light reflective material can be calculated, for example, by the following method.

### Calculation Method of Average Particle Diameter

The particle diameter of the light reflective material powder is calculated by using a scanning electron microscope “TM3030Plus” manufactured by Hitachi High-Tech Corporation, for example. First, one surface of a double-sided tape formed of carbon is attached to a sample stage of the microscope, and thereafter the light reflective material powder is disposed at the other surface of the double-sided tape. The magnification of the microscope is set to be in a range from 1000 powers to 2000 powers to acquire images of 100 powder particles of the light reflective material. Thereafter, the particle diameter of each particle is measured with image analysis software.

In the present specification, the particle diameter of the light reflective material powder means a maximum diameter among the diameters when viewed from one primary surface of the light reflective material. Subsequently, a median diameter of the measured particle is calculated, and the calculated value is set as the average particle diameter of the light reflective material. The particle diameter of the light reflective material powder may be calculated by extracting the cross section of the covering member intermediate 3A with the SEM and measuring it with image analysis software. In addition, the average particle diameter of the light reflective material can be calculated by extracting the cross section of the covering member 3 with the SEM after manufacturing the light-emitting device 1 and measuring it with image analysis software.

Examples of the alkali metal silicate contained in the covering member intermediate 3A include potassium silicate, sodium silicate, and lithium metasilicate.

In the example illustrated in FIGS. 2A to 2E, the light-emitting device intermediate 1A includes a plurality of the light-transmissive members 4 disposed in the respective light-emitting surfaces 23 of the plurality of light-emitting elements 2. However, the light-emitting device intermediate 1A is not limited thereto, and a plurality of the light-emitting elements 2 may be disposed on the primary surface of one light-transmissive member 4.

The light-transmissive member 4 can contain a wavelength conversion material that can convert a wavelength of at least a part of light from the light-emitting element 2. This facilitates chromaticity adjustment of the light-emitting device 1 manufactured by the method according to the present embodiment. The wavelength conversion material contained in the light-transmissive member 4 may be of one type or a plurality of types.

The light-transmissive member 4 may be formed of the wavelength conversion material and a base material, or may be formed of only the wavelength conversion material.

When the light-transmissive member 4 is formed of the wavelength conversion material and the base material, the wavelength conversion material may be contained in the base material or may be disposed on the surface of the base material. When the wavelength conversion material is disposed on the surface of the base material, the wavelength conversion material can be disposed on a surface of the base material facing the light-emitting element 2. In addition, only the wavelength conversion material may be disposed on the surface of the base material, or a resin containing the wavelength conversion material may be disposed on the surface of the base material.

When the wavelength conversion material is contained in the base material, the wavelength conversion material may be dispersed in the base material or may be unevenly distributed in the base material.

Examples of the material of the base material include an inorganic member, such as glass, ceramic, or sapphire, or an organic material, such as a resin or a hybrid resin containing one or more kinds of silicone resins, modified silicone resins, epoxy resins, modified epoxy resins, acrylic resins, phenol resins, and fluorine resins.

As the wavelength conversion material, a known phosphor can be used. For example, as the phosphor, an yttrium aluminum garnet-based phosphor (for example, (Y, Gd)₃(Al, Ga)₅O₁₂:Ce), a lutetium aluminum garnet-based phosphor (for example, Lu₃(Al, Ga)₅O₁₂:Ce), a terbium aluminum garnet-based phosphor (for example, Tb₃(Al, Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba, Sr, Ca, Mg)₂SiO₄:Eu), oxynitride-based phosphors, such as a β-SiAION-based phosphor (for example, (Si, Al)₃(O,N)₄:Eu) and an α-SiAlON-based phosphor (for example, Ca(Si, Al)₁₂(O,N)₁₆:Eu), nitride-based phosphors, such as an LSN-based phosphor (for example, (La, Y)₃Si₆N₁₁:Ce), a BSESN-based phosphor (for example, (Ba, Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr, Ca) AlSiN₃:Eu), fluoride-based phosphors, such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5 MgO·0.5 MgF₂·GeO₂:Mn), a quantum dot having a perovskite structure (for example, (Cs, FA, MA)(Pb, Sn)(F, Cl, Br, I)₃, where FA and MA represent formamidinium and methylammonium, respectively), a II-VI group quantum dot (for example, CdSe), a III-V group quantum dot (for example, InP), a quantum dot having a chalcopyrite structure (for example, (Ag, Cu)(In, Ga)(S, Se)₂), and the like can be used.

The light-transmissive member 4 can contain a light-diffusing material according to purpose. A light-diffusing material known in the art can be employed for the light-diffusing material. Examples of the light-diffusing material include titanium oxide, silicon oxide, aluminum oxide, and barium titanate.

The step of providing the light-emitting device intermediate 1A includes, for example, a step of mixing light reflective material powder, silicon oxide powder, and an alkali metal aqueous solution to form a mixture, a step of covering the light-emitting elements 2 with the mixture, and a step of heating the mixture covering the light-emitting elements 2 to form the covering member intermediate 3A.

Step of Forming Mixture In the step of forming the mixture, the mixture is provided by mixing mixed powder obtained by mixing the light reflective material powder and the silicon oxide powder with the alkali metal aqueous solution. For example, the mixed powder is mixed to the extent of obtaining uniform viscosity and then degassed and agitated with an agitation degassing machine that can perform agitation under reduced pressure.

Because the details of the light reflective material are as described above, the description thereof is omitted here.

The concentration of the alkali metal aqueous solution is in a range from 1 mol/L to 5 mol/L, for example. When the concentration of the alkali metal aqueous solution is excessively low, the mixture may be difficult to cure, and degradation of strength and decomposition of the covering member intermediate 3A may occur. On the other hand, when the concentration of the alkali metal aqueous solution is excessively high, excess alkali metal may precipitate and reduce the reliability of the light-emitting element 2. The alkali metal aqueous solution is potassium hydroxide solution or sodium hydroxide solution, for example.

The weight ratio between the silicon oxide powder and the light reflective material powder is in a range from 1:4 to 1:1, for example. That is, in the silicon oxide powder and the light reflective material powder, the weight of the light reflective material powder is in a range from one time to four times the weight of the silicon oxide powder, for example. The weight ratio between the alkali metal aqueous solution and the mixed powder is in a range from 2:10 to 8:10, for example. That is, in the alkali metal aqueous solution and the mixed powder, the weight of the mixed powder is in a range from 1.25 times to 5 times the weight of the alkali metal aqueous solution. When the weight of the alkali metal aqueous solution is much smaller than the weight of the mixed powder, multiple fine lumps are formed at the time of mixing the mixed powder and the alkali metal aqueous solution, making formation difficult. On the other hand, when the weight of the alkali metal aqueous solution is much larger than the weight of the mixed powder, cracks may occur when the mixture is heated and cured, and the strength of the covering member intermediate 3A obtained through curing may decrease.

### Step of Covering Light-Emitting Elements 2

In the step of covering the light-emitting elements 2, in the example illustrated in FIG. 2A, the surface of the light-transmissive member 4 located at the opposite side to the surface facing the light-emitting elements 2 is not covered with the mixture, but the electrode-forming surface 24 and the lateral surfaces 25 of the light-emitting element 2 and the lateral surfaces 41 of the light-transmissive member 4 are covered with the mixture. As the method of covering the light-emitting element 2 as described above, for example, a flat plate support is provided, the light-transmissive member 4 and the light-emitting element 2 are disposed on the support, and then the mixture is applied from the light-emitting element 2 side. When the light-emitting device intermediate 1A includes the plurality of light-emitting elements 2, the light-emitting elements 2 can be covered with the mixture such that the mixture is supplied in the spaces between adjacent ones of the light-emitting elements 2. Furthermore, when the light-emitting device intermediate 1A includes the plurality of light-transmissive members 4, the light-emitting elements 2 and the light-transmissive members 4 can be covered with the mixture such that the mixture is supplied in the spaces between adjacent ones of the light-transmissive members 4. When the light-emitting device 1 not including the light-transmissive members 4 is manufactured, only the electrode-forming surface 24 of the light-emitting element 2 or the electrode-forming surface 24 and the lateral surfaces 25 of the light-emitting element 2 can be covered with the mixture in this step.

### Step of Forming Covering Member Intermediate 3A

In the step of forming the covering member intermediate 3A, the mixture is heated and cured to form the covering member intermediate 3A. By the heating, the alkali metal and the silicon oxide contained in the mixture react to form the covering member intermediate 3A containing the alkali metal silicate. This step includes, for example, a temporary curing step of curing the mixture at a first temperature T1 and a main curing step of curing the mixture at a second temperature T2 higher than the first temperature T1. The temporary curing step performs heating at the first temperature T1 in a range from 80° C. to 100° C. in a range from 10 minutes to 2 hours, for example. The main curing step performs heating at the second temperature T2 in a range from 150° C. to 250° C. in a range from 10 minutes to 3 hours, for example.

As illustrated in FIG. 2A, when the light-emitting device intermediate 1A includes the plurality of light-emitting elements 2, in the step of providing the light-emitting device intermediate 1A, the light-emitting device intermediate 1A to be provided preferably has groove portions 5 in portions of the covering member intermediate 3A located between adjacent ones of the light-emitting elements 2. Thus, in the step of forming the covering member 3 described later, the alkaline earth metal halide salt aqueous solution 6 enters the groove portions 5, and the area of the covering member intermediate 3A that is in contact with the alkaline earth metal halide salt aqueous solution 6 increases. Therefore, the replacement reaction described later can be performed over a wide range. In addition, in a singulation step described later, singulation can be easily performed by cutting a light-emitting device intermediate 1B after replacement, at the groove portions 5.

When the light-emitting device intermediate 1A includes the plurality of light-transmissive members 4 disposed on the respective light-emitting surfaces 23 of the plurality of light-emitting elements 2 as illustrated in FIG. 2A, or when the light-emitting device intermediate 1A include no light-transmissive member 4, the groove portions 5 may be open to the electrode-forming surface 24 side of the light-emitting elements 2 or open to the light-emitting surface 23 side of the light-emitting elements 2 in the step of providing the light-emitting device intermediate 1A. In addition, the groove portions 5 may penetrate the light-emitting device intermediate 1A, or do not have to penetrate the light-emitting device intermediate LA. In the case of the light-emitting device intermediate 1A in which the plurality of light-emitting elements 2 are disposed on the primary surface of one light-transmissive member 4, in the step of providing the light-emitting device intermediate 1A, the groove portions 5 open on the electrode-forming surface 24 side of the light-emitting elements 2.

### Step of Forming Covering Member 3

The method of manufacturing the light-emitting device 1 of the present embodiment includes a step of immersing the covering member intermediate 3A in the alkaline earth metal halide salt aqueous solution 6 to form the covering member 3 containing alkaline earth metal silicate as illustrated in FIG. 2B. Here, the immersion is not limited to immersion in the alkaline earth metal halide salt aqueous solution 6 in a reactor 7 to allow the alkaline earth metal halide salt aqueous solution to penetrate into the covering member intermediate 3A, but includes injecting or dropping the alkaline earth metal halide salt aqueous solution 6 to allow the alkaline earth metal halide salt aqueous solution to penetrate into the covering member intermediate 3A.

By this step, the alkali metal of the alkali metal silicate constituting the covering member intermediate 3A can be replaced by the alkaline earth metal in the alkaline earth metal halide salt aqueous solution 6. As a result of the replacement reaction, a product of the covering member 3 containing the alkaline earth metal silicate and alkali metal halide salt is formed.

The halogen contained in the alkaline earth metal halide salt dissolved in the alkaline earth metal halide salt aqueous solution 6 is, for example, chlorine, bromine, or iodine. The alkaline earth metal is, for example, calcium, magnesium, or barium. Accordingly, the alkaline earth metal halogen salt is a compound of the above-described halogen and alkaline earth metal.

The alkaline earth metal halide is, for example, calcium chloride or magnesium chloride. When the alkali metal of alkali metal silicate constituting the covering member intermediate 3A is potassium silicate and the alkaline earth metal halide salt aqueous solution 6 is calcium chloride, the covering member 3 containing calcium silicate and the product of potassium chloride is formed by the replacement reaction. When the alkali metal of the alkali metal silicate constituting the covering member intermediate 3A is potassium silicate and the alkaline earth metal halide salt aqueous solution 6 is magnesium chloride, the covering member 3 containing magnesium silicate and the product of potassium chloride is formed by the replacement reaction. Calcium silicate or magnesium silicate is less likely to react with moisture among alkaline earth metal silicates. Therefore, generation of metal ions due to a reaction with moisture can be reduced. As a result, the occurrence of a leakage current caused by contact of the metal ions with the electrode 22 of the light-emitting element 2 can be reduced, and the light-emitting device 1 with high reliability can be manufactured.

The concentration of the alkaline earth metal halide salt aqueous solution 6 is in a range from 0.5 mol/L to 2.5 mol/L, for example. Within the above-described range, the replacement reaction with the alkali metal is easily performed.

In the step of forming the covering member 3, the entire outer surface of the covering member intermediate 3A can be immersed in the alkaline earth metal halide salt aqueous solution 6 so as to be in contact therewith. As a result, the replacement reaction is performed on the entire outer surface constituting the covering member intermediate 3A. Accordingly, with the method of manufacturing the light-emitting device 1 according to the present embodiment, the light-emitting device 1 with high reliability can be manufactured. In the step of forming the covering member 3, a part of the covering member intermediate 3A can be immersed in the alkaline earth metal halide salt aqueous solution 6 so as to be in contact therewith.

In the step of forming the covering member 3, the temperature of the alkaline earth metal halide salt aqueous solution 6 in which the covering member intermediate 3A is immersed is preferably 50° C. or more. This promotes the replacement reaction. Accordingly, with the method of manufacturing the light-emitting device 1 according to the present embodiment, the light-emitting device 1 with high reliability can be manufactured. The time for which the covering member intermediate 3A is immersed in the alkaline earth metal halide salt aqueous solution 6 is preferably 15 hours or more from the viewpoint of sufficiently advancing the replacement reaction. As long as the alkaline earth metal halide salt aqueous solution 6 has a temperature of 50° C. or more, the alkaline earth metal halide salt aqueous solution 6 may be boiled or need not be boiled.

As illustrated in FIG. 2C, after the step of forming the covering member 3, the light-emitting device intermediate 1B after the replacement is taken out from the alkaline earth metal halide salt aqueous solution 6.

### Rinsing Step

The method of manufacturing the light-emitting device 1 according to the present embodiment can include a step of rinsing the covering member 3 after the step of forming the covering member 3. In the replacement reaction, the product of the alkali metal halide salt is formed as described above. Therefore, by performing rinsing, the above-described alkali metal halide salt adhered to the light-emitting device intermediate 1B after the replacement can be removed. At the same time, the unreacted alkaline earth metal halide salt aqueous solution 6 can be removed by performing rinsing. Accordingly, with the method of manufacturing the light-emitting device 1 according to the present embodiment, the light-emitting device 1 with high reliability can be manufactured.

In the rinsing step, water at 50° C. or more is preferably used. As a result, the washing effect is enhanced, and the alkali metal halide salt and the unreacted alkaline earth metal halide salt aqueous solution 6 adhering to the light-emitting device intermediate 1B after the replacement can be further removed. The rinsing time is preferably 15 hours or more from the viewpoint of sufficient washing. An example of the water used for the rinsing includes pure water. Examples of the pure water include reverse osmosis (RO) water, purified water, deionized water, and distilled water.

The method of manufacturing the light-emitting device 1 of the present embodiment can include a step of drying the covering member 3 before and after the rinsing step or after the rinsing step.

### Step of Exposing Electrode

The method of manufacturing the light-emitting device 1 according to the present embodiment can include, after the step of forming the covering member 3, a step of removing a part of the covering member 3 disposed on the electrode-forming surface 24 side of the covering member 3 of the light-emitting device intermediate 1B after replacement to expose the electrodes 22, as illustrated in FIG. 2D. The covering member 3 can be removed by, for example, grinding.

### Singulation Step

As illustrated in FIG. 2E, the method of manufacturing the light-emitting device 1 according to the present embodiment can include a step of cutting the light-emitting device intermediate 1B after the replacement at the groove portions 5 to singulate the light-emitting device intermediate 1B after the step of forming the covering member 3.

For example, cutting can be performed by using a cutting blade, such as a blade, such that the cutting blade passes through the groove portion 5.

### Light-Emitting Device

As illustrated in FIG. 1, the light-emitting device 1 includes the light-emitting element 2 and the covering member 3 that contains the light reflective material and the alkaline earth metal silicate and covers the light-emitting element 2. With this configuration, the alkaline earth metal silicate constituting the covering member 3 is less likely to react with, for example, moisture present in the atmosphere during driving of the light-emitting device 1, and thus the light-emitting device 1 with high reliability can be provided. Details will be described below.

Because the alkaline earth metal silicate has relatively low solubility in water, the alkaline earth metal silicate hardly reacts with moisture. Therefore, generation of metal ions due to reaction with moisture can be reduced, and a leakage current caused by contact of the metal ions with the electrode 22 of the light-emitting element 2 can be reduced.

Hereinafter, members common to the light-emitting device intermediate 1A are the same as those described in the light-emitting device intermediate 1A, and thus description thereof may be omitted.

In the example illustrated in FIG. 1, the covering member 3 covers the electrode-forming surface 24 and the lateral surfaces 25 of the light-emitting element 2.

The light reflective material contained in the covering member 3 is the same as the light reflective material contained in the light-emitting device intermediate 1A, and therefore description thereof is omitted here.

As described above, examples of the alkaline earth metal silicate contained in the covering member 3 include calcium silicate or magnesium silicate. The covering member 3 may or does not have to contain the alkali metal silicate that has not been replaced by the alkaline earth metal silicate when the covering member intermediate 3A is immersed in the alkaline earth metal halide salt aqueous solution 6. When the covering member 3 contains alkali metal silicate, for example, at least half or more of the alkali metal silicate contained in the covering member intermediate 3A is preferably replaced by the alkaline earth metal silicate.

The resistivity of the covering member is preferably 1.0×10¹¹ Ω·cm or more. For example, the resistivity is in a range from 1.0×10¹¹ Ω·cm to 1.0×10¹² Ω·cm. Within the above-described range, the covering member can be used as an insulating member of the light-emitting device 1, and the reliability of the light-emitting device 1 can be improved.

In the example illustrated in FIG. 1, the light-emitting device 1 includes the light-transmissive member 4 disposed on the light-emitting surface 23 of the light-emitting element 2. The covering member 3 covers the lateral surfaces 41 of the light-transmissive member 4. An upper surface 42 of the light-transmissive member 4 exposed from the covering member 3 is a light exiting surface 11 of the light-emitting device 1. The covering member 3 partially constitutes the outer surfaces of the light-emitting device 1.

The light-transmissive member 4 may be disposed on the light-emitting surface 23 of the light-emitting element 2 via an adhesive, or may be directly disposed on the light-emitting surface 23 without an adhesive.

In the example illustrated in FIG. 1, the light-emitting device 1 includes the light-transmissive member 4. However, the light-emitting device 1 is not limited to this and does not have to include the light-transmissive member 4. When the light-emitting device 1 does not include the light-transmissive member 4, the light-emitting surface 23 of the light-emitting element 2 serves as the light exiting surface 11 of the light-emitting device 1.

Because the details of the light-transmissive member 4 are as described above, the description thereof is omitted here.

In the example illustrated in FIG. 1, the light-emitting device 1 does not include a wiring substrate. However, the light-emitting device 1 is not limited thereto, and may include a wiring substrate. When the light-emitting device 1 includes a wiring substrate, the electrode 22 of the light-emitting element 2 is electrically connected to the wiring of the wiring substrate. In addition, on the surface of the wiring substrate facing the light-emitting element, the covering member 3 can be disposed in a region other than the region electrically connected to the electrode 22 of the light-emitting element 2. Further, one light-emitting element 2 may be electrically connected to one wiring substrate, or the plurality of light-emitting elements 2 may be electrically connected to one wiring substrate. As a base material of the wiring substrate, aluminum nitride can be used, for example.

### EXAMPLES

Hereinafter, the embodiment will be described more specifically with reference to the examples.

A mixed powder obtained by mixing boron nitride powder having an average particle diameter of 10 μm and an average aspect ratio of 20 and silicon oxide powder having an average particle diameter of 0.4 μm as a median diameter was mixed with a potassium hydroxide solution having a concentration of 3 mol/L to provide a mixture. The silicon oxide powder and the boron nitride powder were mixed at a weight ratio of 3:5. The potassium hydroxide solution and the mixed powder were mixed at a weight ratio of 3.8:9. The mixed powder and the potassium hydroxide solution were mixed to the extent of obtaining uniform viscosity and then degassed and agitated with an agitation degassing machine that was able to perform agitation under reduced pressure.

Subsequently, the mixture was subjected to temporary curing by heating it at a first temperature of 90° C. under a pressure of 1 MPa for one hour. Subsequently, the mixture was subjected to main curing by heating it at a second temperature of 200° C. under a pressure of 1 MPa for two hours, and thus the covering member intermediate was produced.

The covering member intermediate was immersed in a calcium chloride solution having a concentration of 1.5 mol/L at 70° C. for 17 hours to form a covering member. The covering member was immersed in water at 70° C. for 17 hours and rinsed, and then vacuum-dried at 40° C. for 30 minutes.

Elemental analysis by X-ray diffraction (XRD) was performed on the covering member intermediate and the covering member according to the example. As a result, calcium was detected in the covering member, and the content of potassium decreased in the covering member intermediate. Accordingly, it was confirmed that the potassium in the potassium silicate contained in the covering member intermediate was replaced by calcium derived from the calcium chloride solution.

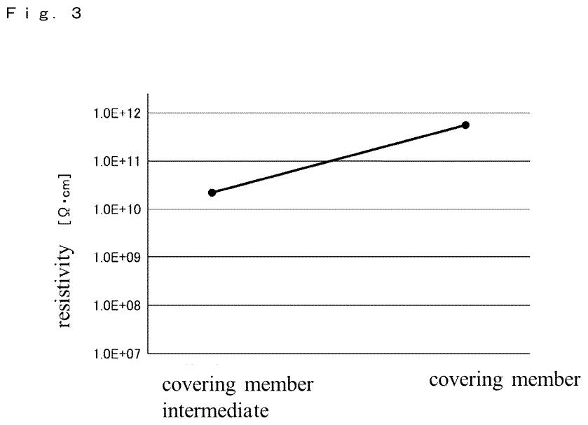

In addition, for the covering member intermediate and the covering member according to the example, the resistivity was measured by a high-resistance resistivity meter (Hiresta-UP (model number: MCP-HT450) manufactured by Mitsubishi Chemical Corporation). The measurement results are illustrated in FIG. 3. FIG. 3 is a graph showing the resistivities of the covering member intermediate and the covering member according to the example. The resistivity of the covering member intermediate was 2.19×10¹⁰ Ω·cm, and the resistivity of the covering member was 5.09×10¹¹ Ω·cm. As illustrated in FIG. 3, also from the fact that the resistivity of the covering member increased with respect to the resistivity of the covering member intermediate, it was confirmed that the potassium in the potassium silicate contained in the covering member intermediate was replaced by the calcium derived from the calcium chloride solution.

What is claimed is:

1. A method of manufacturing a light-emitting device, comprising:
providing a light-emitting device intermediate including a light-emitting element and a covering member intermediate that contains a light reflective material and an alkali metal silicate and covers the light-emitting element; and
forming a covering member containing an alkaline earth metal silicate by immersing the covering member intermediate in an aqueous solution containing an alkaline earth metal halide salt.

2. The method according to claim 1, wherein
in the forming of the covering member, the covering member intermediate is immersed such that an entire outer surface of the covering member intermediate is in contact with the aqueous solution containing the alkaline earth metal halide salt.

3. The method according to claim 1, wherein
the light-emitting device intermediate includes a plurality of the light-emitting elements and the covering member intermediate covering the plurality of light-emitting elements and linking adjacent ones of the light-emitting elements, and
in the providing of the light-emitting device intermediate, the covering member intermediate includes a groove portion located between the adjacent ones of the light-emitting elements.

4. The method according to claim 3, wherein
a concentration of the alkaline earth metal halide salt in the aqueous solution containing the alkaline earth metal halide salt is in a range of 0.5 mol/L to 2.5 mol/L.

5. The method according to claim 4, wherein
the alkaline earth metal halide salt is calcium chloride or magnesium chloride.

6. The method according to claim 5, wherein
the light reflective material is boron nitride or aluminum oxide.

7. The method according to claim 6, comprising rinsing the covering member after forming the covering member.

8. The method according to claim 7, wherein
in the rinsing of the covering member, water at 50° C. or more is used.

9. A light-emitting device, comprising:
a light-emitting element; and
a covering member containing a light reflective material and an alkaline earth metal silicate and covering the light-emitting element.

10. The light-emitting device according to claim 9, wherein
the alkaline earth metal silicate is calcium silicate or magnesium silicate.

11. The light-emitting device according to claim 10, wherein
the light reflective material is boron nitride or aluminum oxide.

12. The light-emitting device according to claim 11, wherein
the covering member has a resistivity in a range of 1.0×10¹¹ Ω·cm to 1.0×10¹² Ω·cm.

13. The light-emitting device according to claim 12, further comprising:
a light-transmissive member disposed on a light-emitting surface of the light-emitting element,
wherein the covering member covers a lateral surface of the light-transmissive member.
